(19) United States
(12) Patent Application Publication
(10) Pub. No.: US 2007/0069745 A1
(43) Pub. Date: Mar. 29, 2007

(54) PROBE CARD FOR INTEGRATED CIRCUITS

(75) Inventors: Choon-Leong Lou, Singapore (SG); Mei-Shu Hsu, Bade City, (TW)

Correspondence Address: CONNOLLY BOVE LODGE & HUTZ LLP, P.O. BOX 2207, WILMINGTON, DE, 19899-2207, US

(73) Assignee: STAR TECHNOLOGIES INC., Jhundong Township (TW)

(21) Appl. No.: 11/164,908

(22) Filed: Dec. 9, 2005

(30) Foreign Application Priority Data
Sep. 28, 2005 (TW) 094133675

(51) Int. Cl. G01R 31/02

(52) U.S. Cl. 324/754

(57) ABSTRACT

A probe card for integrated circuit devices comprises a printed circuit board, at least one probe pin positioned on the printed circuit board, and at least one ultrasonic generator configured to generate ultrasonic energy. When the probe pin contacts a pad, the ultrasonic generator emits ultrasonic energy to vibrate the probe pin so as to form a recess on the surface of a dielectric layer such as an oxide layer on the pad, and the probe pin is then pressed downward to scratch the dielectric layer to form a signal channel. While some contaminants such as oxide fragments usually adhere to the probe pin when the probe card is used to perform an electrical test of the integrated circuit device, the present invention can use ultrasonic energy to vibrate the probe pin so as to remove contaminants from the probe pin.

### BACKGROUND OF THE INVENTION

1. Field of the Invention

The present invention relates to a probe card for integrated circuits, and more particularly, to a probe card for integrated circuits which uses ultrasonic energy to vibrate a probe pin of the probe card to scratch a dielectric layer on a pad of the integrated circuit so as to decrease the contact resistance between the probe pin and the pad.

2. Description of the Related Art

Generally, it is necessary to test electrical properties of integrated circuit devices on the wafer level to verify that the integrated circuit device satisfies the product specification. Integrated circuit devices with all electrical properties satisfying specifications are selected to continue through the subsequent packaging process, while other devices are discarded to avoid additional packaging cost. Another electrical property test is performed on the integrated circuit device after the packaging process is completed to sieve out unsatisfactory devices so as to increase product yield. In other words, the integrated circuit device undergoes several tests during the manufacturing process.

FIG. 1 illustrates a probe card 10 applied to the electrical test of an integrated circuit device 20 according to the prior art. The probe card 10 uses a probe pin 12 to contact a pad 22 of the integrated circuit device 20 to form a signal path for transmitting test signals to the integrated circuit device 20 and transmitting test parameters to a test machine (not shown in the drawing). A dielectric layer 24 such as an oxide layer is usually formed on the surface of the pad 22 due to the native oxidation, and the resistance of the dielectric layer 24 is very high, which is adverse to the formation of the signal path. Consequently, after the tip of the probe pin 12 contacts the surface of the pad 22, the probe pin 12 is pressed downward about 60 to 70 micrometers so that the tip of the probe pin 12 can pierce the dielectric layer 24 to form the signal path. However, the dielectric layer 24 on the surface of the pad 22 possesses a high hardness, which usually causes the probe pin 12 to slide on the dielectric layer 24 since the probe pin 12 may be unable to penetrate the dielectric layer 24. To pierce the dielectric layer 24, the conventional technique overdrives the probe pin 12 such that the tip of the probe pin 12 can pierce the dielectric layer 24 to conquer the hardness of the dielectric layer 24.

As the semiconductor fabrication technique proceeds into the nanometer scale, the line width and the pitch shrink correspondingly, which results in RC-delay effect due to an increased conductor resistance and capacitance between conductors. RC-delay has many negative influences such as a decreased signal propagation speed, an increased cross talk noise and power consumption, wherein the decreased signal propagation speed is the most serious one. To reduce the RC-delay effect, researchers use porous low-k dielectric material to prepare the dielectric structure between conductors in the advanced integrated circuit fabrication process.

Conventional dielectric material such as silicon dioxide possesses higher mechanical properties to sustain the applied force as the probe pin 12 is overdriven. But, the porous low-k dielectric material used in the advanced integrated circuit fabrication process possesses lower mechanical properties, which can not sustain the applied force as the probe pin 12 is overdriven above 70 micrometers. Consequently, piercing the hard dielectric layer 24 by overdriving the probe pin 12 may cause the porous low-k dielectric material below the pad 22 to collapse due to unsustainable force applied by the probe pin 12. This destroys the dielectric structure between conductors and the integrated circuit device 20 fails or is damaged.

In addition, contaminants such as oxide fragment adhere to the probe pin 12 when the probe card 10 is used to perform electrical tests of the integrated circuit device 20. An on-line cleaning process may be performed to remove the contaminants from the probe pin 12 by brushing the probe pin 12 on a cleaning pad of the test machine. However, the cleaning process is controlled by the test machine and requires a length of time, reducing efficiency. Further, the conventional cleaning process can not completely remove all contaminants, and some contaminants may remain on the probe pin 12. More particularly, the brushing movement of the cleaning process often damages the probe pin 12. An off-line cleaning process may be performed by dipping the probe pin 12 into a cleaning solution to remove the contaminants from the probe pin 12 according to the prior art.

### SUMMARY OF THE INVENTION

The objective of the present invention is to provide a probe card for integrated circuits which uses ultrasonic energy to vibrate a probe pin of the probe card to scratch a dielectric layer on a pad of the integrated circuit so as to decrease the contact resistance between the probe pin and the pad, and method for cleaning the probe pin by the ultrasonic energy.

In order to achieve the above-mentioned objective and avoid the problems of the prior art, one embodiment of the present invention discloses a probe card comprising a first substrate, at least one probe pin positioned on the first substrate, and an ultrasonic generator positioned on the first substrate to generate ultrasonic energy to vibrate the probe pin. The ultrasonic generator may be positioned on a second substrate, which can be assembled to the first substrate when the probe card is used to perform electrical tests. In addition, the ultrasonic generator and its power supply may be incorporated in a test head of a test machine, and the ultrasonic generator can acquire operation power from a power supply of the test head to generate the ultrasonic energy to vibrate the probe pin when the test head is docked to the probe card.

When the probe pin contacts a pad of an integrated circuit device under test, the ultrasonic generator can emit the ultrasonic energy to vibrate the probe pin so as to form a recess on a dielectric layer on the pad, and the probe pin is then pressed downward to contact the pad through the recess with low overdrive forming a signal path. Preferably, the ultrasonic energy can vibrate the probe pin in an XYZ 3-dimensional manner. In addition, the ultrasonic energy may vibrate the probe pin to brush the surface of the pad or scratch the dielectric layer on the surface of the pad when the probe pin contacts the surface of the pad of the integrated circuit device, with the ultrasonic energy preferably vibrating the probe pin in an XY 2-dimensional manner. Consequently, the contact resistance between the probe pin and the pad can be decreased due to improved contact between the probe pin and the pad with the dielectric removed.

In short, the embodiment of the present invention uses ultrasonic energy to vibrate the probe pin to form the recess and then presses the probe pin downward to contract the surface of the pad with low overdrive, or to vibrate the probe pin to brush the surface of the pad to decrease the contact resistance by increasing the contact between the probe pin and the pad. In addition, contaminants such as oxide fragment adhere to the probe pin when the probe card is used to perform electrical tests of the integrated circuit device, and ultrasonic energy can be used to vibrate the probe pin to remove any adhered contaminants from the probe pin.

Conventional technique must overdrive the probe pin continuously to scratch the dielectric layer on the surface of the pad, which is likely to result in a sliding probe pin or in collapse of the porous low-k dielectric material below the pad under high probe pressure, causing the dielectric structure between conductors to be damaged. Conversely, when the probe pin contacts the surface of the pad, the embodiment of the present invention uses ultrasonic energy to vibrate the probe pin to form the recess and then with low overdrive causing the probe pin to contract the pad, forming the signal path. Since the recess can automatically locate the position of the probe pin to avoid the occurrence of the sliding probe, the pad can be contacted precisely.

In addition, the probe pin can scratch the dielectric layer without overdriving the probe pin since the ultrasonic energy vibrates the probe pin to form the recess before the probe pin is pressed downward to scratch the dielectric layer at the precise location of the recess. Consequently, the present invention can prevent the porous low-k dielectric material below the pad from collapsing to maintain the dielectric structure between conductors since the probe pin can scratch the dielectric layer on the pad without overdriving.

Further, ultrasonic energy may be used to vibrate the probe pin to brush the surface of the pad to clear the dielectric layer on the pad. The probe pin then contacts the pad of the integrated circuit device, and the contact resistance can be decreased as a result of improved contact between the probe pin and the pad. In addition, ultrasonic energy can also be used to vibrate the probe pin to remove contaminants during tests.

### BRIEF DESCRIPTION OF THE DRAWINGS

The objectives and advantages of the present invention will become apparent upon reading the following description and upon reference to the accompanying drawings in which:

FIG. 1 illustrates a probe card applied to the electrical test of an integrated circuit device according to the prior art;

FIG. 2 and FIG. 3 illustrate a probe card according to a first embodiment of the present invention;

FIG. 4 and FIG. 5 illustrate a probe card applied to the electrical test of an integrated circuit device according to a first embodiment of the present invention; and

FIG. 6 illustrates a probe card according to a second embodiment of the present invention.

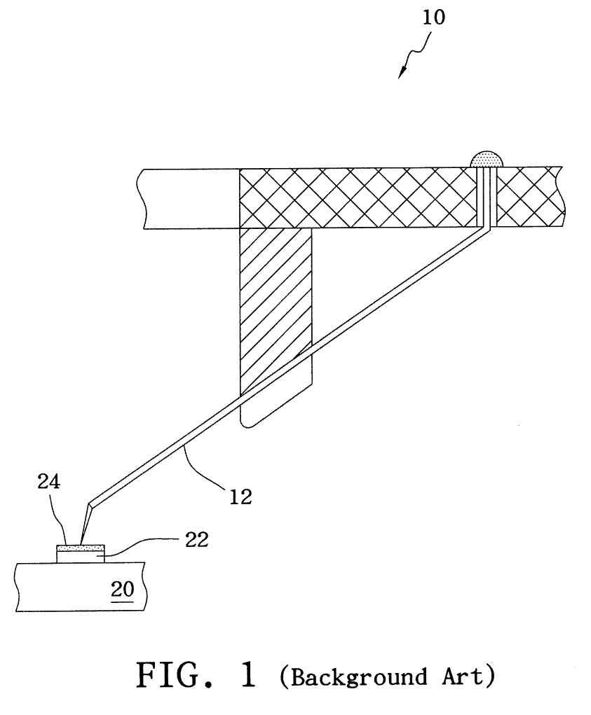

### DETAILED DESCRIPTION

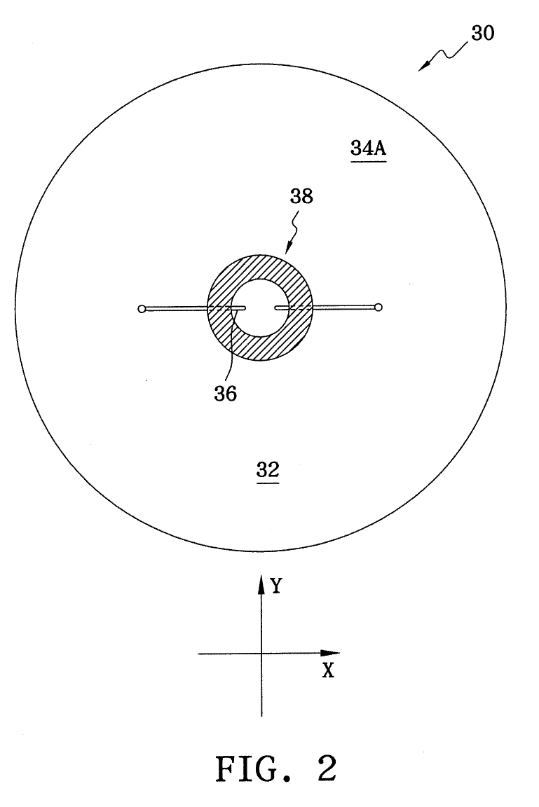

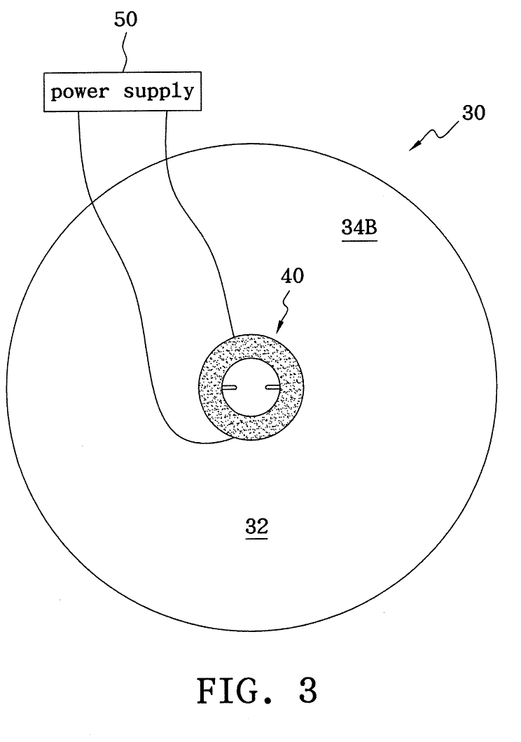

FIG. 2 and FIG. 3 illustrate a probe card 30 according to a first embodiment of the present invention. The probe card 30 comprises a first substrate 32, a plurality of probe pins 36 positioned on a first surface 34A of the first substrate 32, and an ultrasonic generator 40 positioned on a second surface 34B of the first substrate 32. The ultrasonic generator 40 may be made of piezoelectric material such as lead zirconate titanate (PZT) to generate ultrasonic energy to vibrate the probe pin 36, and acquire operation power from an external power supply 50. Alternatively, the ultrasonic generator 40 can acquire operation power from the probe card 30 as well. Further, the ultrasonic generator 40 and the power supply 50 may be incorporated in a test head of a test machine (not shown in the drawing), and the ultrasonic generator 40 can acquire operation power from a power supply of the test head to generate ultrasonic energy to vibrate the probe pin 36 when the probe card 30 is assembled to the test head.

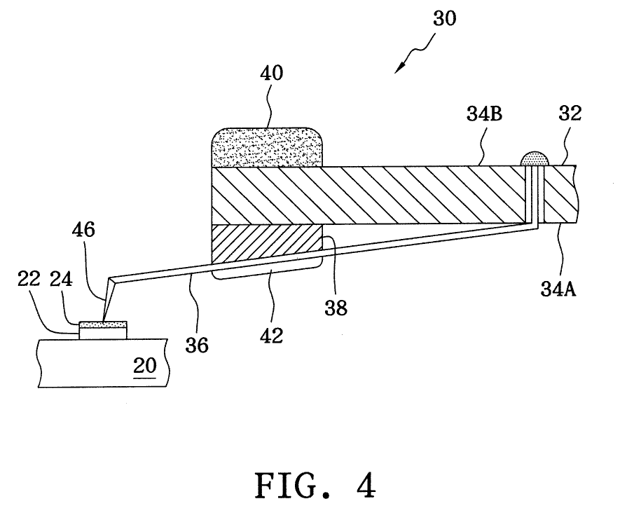

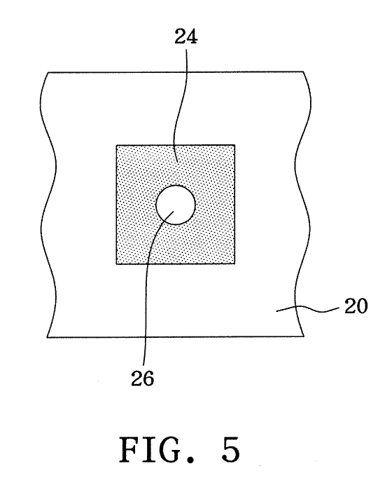

FIG. 4 and FIG. 5 illustrate the probe card 30 applied to the electrical test of an integrated circuit device 20 according to a first embodiment of the present invention. The probe pin 36 is positioned on the first surface 34A of the first substrate 32 via a supporter 38 and an epoxy resin 42. The first substrate 32 can be a circuit board made of ceramic, polyimide with glass fiber, or FR-4. The probe pin 36 can be made of tungsten, alloy of tungsten or rhenium. The supporter 38 can be made of ceramic. The integrated circuit device 20 includes a pad 22 made of conductive material such as aluminum, copper, or gold. When the probe pin 36 contacts the pad 22 of the integrated circuit device 20, the ultrasonic generator 40 can emit the ultrasonic energy to vibrate the probe pin 36 so as to form a recess 26 with a hold in the dielectric layer 24 on the pad 22, and the probe pin 36 is then overdriven downward contact the pad 22 to form a signal path. Although the embodiment uses the probe pin 36 in a cantilever form for example, one skilled in the art may appreciate that the present invention can be applied to other types of probe pins such as the vertical probe pin.

Preferably, after the probe pin 36 contacts the pad 22 of the integrated circuit device 20 and the probe pin 36 is then overdriven downward a small distance, the ultrasonic generator 40 is activated to emit ultrasonic energy to form the recess 26. The duration, operation power, and vibration type of the ultrasonic energy depend on the type of the probe pin 32, the pad 22, and the dielectric layer 24. Consequently, the operation parameter of the ultrasonic generator 40 can be determined according to experimental results or a standard set of reference preset parameters.

Referring back to FIG. 2, the ultrasonic energy preferably vibrates the probe pin 32 along Z direction, X direction, or Y direction, and the tip 46 of the probe pin 36 is pressed downward slightly to pierce into the dielectric layer 24 after the recess 26 is formed by vibrating the probe pin 36. Thus, instead of overdriving the probe pin according to the prior art, the present invention can be used to scratch the dielectric layer 24 by the ultrasonic energy to slightly vibrate the probe pin 36 so as to form the recess 26, and then with low overdrive on the probe pin 36 downward to contact the pad 22 so as to form a signal path.

Generally speaking, a tiny point of contact is formed between the probe pin 36 and the pad 22 by simply overdriving the probe pin 36 downward, and the contact resistance is higher. To decrease the contact resistance, the present invention can activate the ultrasonic generator 40 as the probe pin 36 contacts the pad 22 to generate ultrasonic energy to vibrate the probe pin 36 in an XY 2-dimensional manner so as to scratch the dielectric layer 24 and remove oxide fragments between the probe pin 36 and the pad 22. As a result, the contact resistance can be decreased due to improved contact between the probe pin 36 and pad 22. Even with no dielectric layer 24 on the surface of the pad 22, the ultrasonic energy can be used to vibrate the probe pin 36 in XY 2-dimensional manner so as to brush the surface of the pad 22 removing any interface impurities or particles. Consequently, the contact resistance can also be decreased since there is improved contact between the probe pin 36 and pad 22.

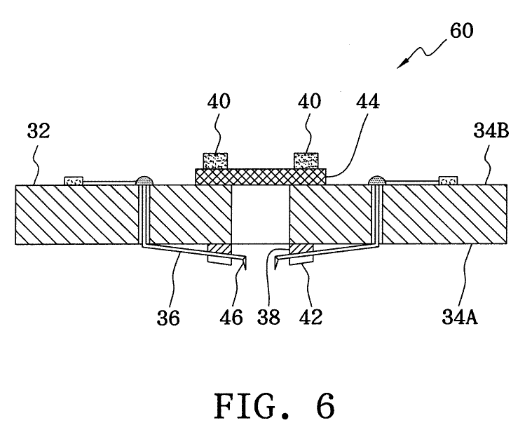

FIG. 6 illustrates a probe card 60 according to a second embodiment of the present invention. Compared to the probe card 30 shown in FIG. 4, the ultrasonic generator 40 of the probe card 60 shown in FIG. 6 is positioned on a second substrate 44, which can be assembled to the second surface 34B of the first substrate 32. Particularly, the ultrasonic generator 40 can be positioned anywhere or on an external substrate such as the second substrate 44, and coupled to the first substrate 42 to generate the ultrasonic energy to vibrate the probe pin 36 when the probe card 60 is used to perform electrical testing. Further, the ultrasonic generator 40 can connect to the first substrate 32 or the probe pin 36 in any manner so long as the generated ultrasonic energy can drive the probe pin 36 to vibrate in a reciprocating pattern to scratch the dielectric layer 24.

As an alternative to the conventional technique for cleaning the probe pin, the present invention can be used to clean the probe pin 36 by placing the probe pin 36 on a cleaning pad when the probe card 30 is assembled on the probe station and then activating the ultrasonic generator 40 to emit ultrasonic energy, thereby vibrating the probe pin 36 on the cleaning pad in a reciprocating manner to remove adhered contaminants. The present invention can perform the on-line cleaning process for the probe pin 36 during intervals between actual electrical tests. Since ultrasonic energy vibrates the probe pin 36 in a reciprocating manner, adhered contaminants can be effectively removed without damaging the probe pin 36. In addition, when the probe card 30 is not used to perform electrical tests, the ultrasonic generator 40 can emit ultrasonic energy to vibrate the probe pin 36 to remove adhered contaminants, thereby performing the cleaning process off-line. In short, the present invention can perform the on-line and off-line cleaning processes for the probe pin 36 more effectively than could the prior art.

Conventional technique must overdrive the probe pin continuously to scratch the dielectric layer on the surface of the pad, which is likely to result in a sliding probe pin or in collapse of the porous low-k dielectric material below the pad, resulting in damage to the dielectric structure between conductors. In the present embodiment, conversely, when the probe pin contacts the surface of the pad, ultrasonic energy is used to vibrate the probe pin to form the recess and then presses the probe pin downward to scratch the dielectric layer to form the signal path. Since the recess can automatically locate the position of the probe pin to avoid the occurrence of the sliding probe, the dielectric layer can be scratched precisely.

In addition, the probe pin can scratch the dielectric layer with minimal or without overdriving the probe pin since the ultrasonic energy vibrates the probe pin to form the recess before the probe pin is overdriven downward to contact the pad at the precise location of the recess. Consequently, the present invention can prevent the porous low-k dielectric material below the pad from collapsing to maintain the dielectric structure between conductors since the probe pin can scratch the dielectric layer on the pad with minimum or with no overdrive.

Ultrasonic energy may be used to vibrate the probe pin to brush the surface of the pad or the dielectric layer on the pad when the probe pin contacts the pad of the integrated circuit device, and the contact resistance can be decreased due to improved contact between the probe pin and the pad. In addition, ultrasonic energy can also be used to vibrate the probe pin to remove contaminants.

The above-described embodiments of the present invention are intended to be illustrative only. Numerous alternative embodiments may be devised by those skilled in the art without departing from the scope of the following claims.

What is claimed as new and desired to be protected by Letters Patent of the United States is:

1. A probe card for integrated circuits, comprising:
a first substrate;
at least one probe pin positioned on the first substrate; and
at least one ultrasonic generator configured to generate ultrasonic energy to vibrate the probe pin.

2. The probe card for integrated circuits of claim 1, wherein the ultrasonic generator is positioned on the first substrate.

3. The probe card for integrated circuits of claim 1, wherein the probe pin is positioned on a first surface of the first substrate and the ultrasonic generator is positioned on a second surface of the first substrate.

4. The probe card for integrated circuits of claim 1, wherein the ultrasonic generator is positioned on a second substrate, the probe pin is positioned on a first surface of the first substrate, and the second substrate is positioned on a second surface of the first substrate.

5. The probe card for integrated circuits of claim 1, wherein the ultrasonic generator is positioned on a test head.

6. The probe card for integrated circuits of claim 1, wherein the ultrasonic generator acquires operation power from the probe card.

7. The probe card for integrated circuits of claim 1, wherein the ultrasonic generator acquires operation power from an external power supply.

8. A method for scratching a dielectric layer on a pad, characterized by moving a probe pin to contact the pad and vibrating the probe pin to scratch the dielectric layer on the pad.

9. The method for scratching a dielectric layer on a pad of claim 8, wherein the probe pin is vibrated by ultrasonic energy.

10. The method for scratching a dielectric layer on a pad of claim 9, wherein the ultrasonic energy vibrates the probe pin in a reciprocating manner.

11. The method for scratching a dielectric layer on a pad of claim 9, wherein the ultrasonic energy vibrates the probe pin to form a recess on the surface of the dielectric layer.

12. The method for scratching a dielectric layer on a pad of claim 11, wherein the probe pin is moved downward to pierce the dielectric layer after the recess is formed.

13. A method for decreasing contact resistance between a probe pin and a pad, characterized by moving the probe pin to contact the pad and vibrating the probe pin to increase the contact between the probe and the pad.

14. The method for decreasing contact resistance between a probe pin and a pad of claim 13, wherein the probe pin is vibrated by ultrasonic energy.

15. The method for decreasing contact resistance between a probe pin and a pad of claim 14, wherein ultrasonic energy vibrates the probe pin to brush the surface of the pad.

16. The method for decreasing contact resistance between a probe pin and a pad of claim 14, wherein ultrasonic energy vibrates the probe pin in a reciprocating manner.

17. A method for cleaning a probe pin, characterized by using ultrasonic energy to vibrate the probe pin to remove contaminants from the probe pin.

18. The method for cleaning a probe pin of claim 17, wherein ultrasonic energy vibrates the probe pin in a reciprocating manner.

19. The method for cleaning a probe pin of claim 17, wherein a tip of the probe pin is positioned on a cleaning pad before the probe pin is vibrated.

20. The method for cleaning a probe pin of claim 19, wherein ultrasonic energy vibrates the probe pin on the cleaning pad in a reciprocating manner.
